(19) United States
(12) Patent Application Publication
(10) Pub. No.: US 2011/0214738 A1
(43) Pub. Date: Sep. 8, 2011

(54) CONCENTRATING PHOTOVOLTAIC MODULE

(75) Inventors: Izhar Halahmi, Hod Hasharon (IL); Pasha Solel, Tel Aviv (IL); Itay Baruchi, Tel Aviv (IL)

(73) Assignee: PYTHAGORAS SOLAR INC., Wilmington, DE (US)

(21) Appl. No.: 13/128,678

(22) PCT Filed: Nov. 12, 2009
(86) PCT No.: PCT/IL2009/001063

§ 371 Date: May 11, 2011

Related U.S. Application Data
(62) Division of application No. 61/193,259, filed on Nov. 12, 2008.

(51) Int. Cl. H01L 31/0203; C08F 290/06; C08F 265/04; C08F 2/50; H01L 31/0232

(52) U.S. Cl. 136/259; 522/96; 522/120

(57) ABSTRACT

Provided is a photo/thermo curable liquid encapsulant formulation for use in the construction of a variety of optical assemblies. Also provided are such optical assemblies.

### FIELD OF THE INVENTION

This invention relates to a light curable encapsulant for use in the construction of photovoltaic cells and modules.

### BACKGROUND OF THE INVENTION

Solar radiation is utilized by various methods to produce useable energy. One method involves the use of photovoltaic (PV) cells, which convert solar radiation to electricity. The cost per unit power for producing electricity using photovoltaic cells can be decreased by concentrating the sunlight so that the same amount of sunlight can impinge a smaller, and thus cheaper, photovoltaic cell, from which a similar or equal amount of electricity may be extracted.

The price of a PV panel is primarily dominated by the cost of each of the materials used and the cost of its assembly. In a low concentration PV panel, the cost of the PV cells is significantly reduced (by 75-90%), but the cost of other materials increases and becomes an important factor. The assembly of low concentration PV panel is also more complex therefore more expensive.

Typical PV panels that are already in the market utilize polymeric mass that encapsulates the cell and conductors and at the same time adheres to the cell and to a protective layer, to seal and protect the PV. The encapsulants dominating the market are thermoplastics that are laminated under pressure and heat, usually between the PV cell and one or more protective layers, usually glass. The disadvantages of thermoplastic encapsulants, such as ethylene vinyl acetate (EVA), polyvinyl butyral (PVB) and ionomer resins are the need for high pressures and temperatures during lamination, their tendency to leave voids, tendency to yellow during exposure to UV light and heat, the need for long curing periods (negative economical aspect), high modulus of elasticity that may break thin PV cells, and their poor adhesion to materials other than the materials of the PV cell and glass.

As an alternative, addition curing silicones have been used as encapsulants. The market share of that kind of encapsulants is relatively low, due to their high price and tendency to be inhibited. The advantages of silicones are high stability against yellowing and discoloration, low modulus of elasticity, and wide service temperature latitude. The disadvantages are poor adhesion to plastic materials, low strength, and high risk of inhibition during curing and long curing time.

The problem becomes critical when a concentrating object (CO) usually made of a transparent amorphous plastic material, such as poly methyl methacrylate (PMMA), cyclic olefin (COC) or polycarbonate (PC) is provided on top of the PV cell in order to increase the light intensity, to form a concentrating PV (CPV). In such a case, the thermoplastic encapsulants are not applicable since their lamination process is at temperatures higher than the softening temperature of the transparent plastic materials and their adhesion to the plastics is poor. The alternative of utilizing addition curing silicones is also not very promising as such silicones have poor adhesion to the plastics, especially to PMMA that is commonly used as a CPV optical element.

### SUMMARY OF THE INVENTION

The inventors of the invention disclosed herein have now developed a reliable, cost effective, encapsulated concentrating PV (CPV) that has excellent dimensional stability and discoloration resistance, obviating the use of thermoplastic encapsulants and silicone encapsulants. The inventors further provide an encapsulant formulation that is a liquid at room temperature, cures readily when exposed to light and/or heat, has a high degree of transparency, high resistance to yellowing and cracking when exposed to sunlight, enough softness (low shore hardness and low modulus of elasticity) and flexibility to withstand the thermal mismatch between the transparent (amorphous) plastic materials and the glass/PV silicon during thermal cycling, has low haze and excellent adhesion to transparent (amorphous) plastic materials, such as poly methyl methacrylate (PMMA), cyclic olefin (COC) and polycarbonate (PC) to glass and/or to the silicon PV cell.

Thus, the invention provides, in one of its aspects, a photo curable or thermo curable liquid encapsulant formulation for bonding to a transparent (amorphous) plastic surface, (e.g., for encapsulating a photovoltaic cell and for bonding same to at least one plastic surface material such as plastic optics), comprising at least one high durability polymer (HDP), at least one unsaturated monomer and/or oligomer, and at least one photoinitiator.

In some embodiments, said at least one HDP is at least one acrylic or methacrylic polymer (namely, a polymer or oligomer having at least 50% of its chain, repeating units derived from acrylic and/or methacrylic acid, ester, urethane or amide thereof). Thus, in such embodiments the liquid encapsulant formulation comprises at least one acrylic polymer, at least one unsaturated monomer and/or oligomer and at least one photoinitiator and optionally at least one free radical source (to permit, upon exposure to light and/or heat, cross-linking and chain growth of the unsaturated monomers and oligomers, to thereby provide a soft and elastic mass).

In other embodiments, said at least one HDP polymer is selected from aliphatic polyester, aliphatic polyurethane, and a poly vinyl butyral.

The liquid encapsulant of the invention wets the surfaces to be bonded substantially without the need to apply pressure and to heat the surface. In some embodiments, the encapsulant formulation of the invention has a viscosity of between about 50 and 1,000 cps at 25° C. at a shear rate of 10 sec⁻¹. In other embodiments, the encapsulant has a viscosity of between about 150 and 5,000 cps at 25° C. at a shear rate of 10 sec⁻¹. In still further embodiments, the encapsulant has a viscosity of between about 250 and 10,000 cps at 25° C. at a shear rate of 10 sec⁻¹.

As a person skilled in the art would appreciate, a higher viscosity (higher content of high molecular weight oligomers and polymers) correlates to a higher strength, fatigue resistance, toughness and stress cracking, faster curing and lower tendency to oxygen inhibition. However, a higher viscosity may also result in the trapping of air between the substrate and the adhesive layer and slowing down of its flow. A lower viscosity (lower molecular weight monomers and oligomers content in the formula is increased) is, on the other hand, correlated to higher brittleness, risk of stress cracking of the bonded (amorphous) transparent polymeric surface, slower curing speed, higher tendency to inhibition by oxygen and higher risk of irritations to operators.

In some embodiments, the at least one HDP is a homopolymer, copolymer or a terpolymer (random, alternate, graft or block) of acrylic or methacrylic acid esters, amides, urethanes or ethers. Non-limiting examples of such acrylic or methacrylic acid esters, amides or ethers (both acrylic acid and methacrylic acid derivatives) are butyl acrylate, ethyl acrylate, octyl acrylate, decyl acrylate, iso-decyl acrylate, tridecyl acrylate, ethyl hexyl acrylate, ethoxylated ethyl hexyl acrylate, octyl decyl acrylate, di-ethylene glycol 2-ethylhexyl ether acrylate, tetra decyl acrylate, cetyl acrylate, stearyl acrylate, behenyl acrylate, polyethylene glycol mono acrylate, urethane acrylate, and caprolactone acrylate.

As used herein, the terms “copolymer” and “terpolymer” as known in the art, independently of each other, refer to one or more types of monomers copolymerized by any means and selected in non limiting manner from random, block, alternate and graft copolymers and terpolymers.

Without wishing to be bound by theory, the at least one acrylic polymer utilized in the formulation of the invention provides the liquid encapsulant controlled reaction rate during exposure to light or heat, controlled viscosity, so that the flow of the liquid encapsulant over the glass/PV silicon is controlled, and provides the cured (after exposure to light and/or heat) encapsulant with the ability to bond the PV cell to an (amorphous) transparent plastic surface such as PMMA, COC and PC, with resilience, elasticity at low temperatures (below zero degrees), strength, high transparency, low level or even zero stress-cracking to plastic surfaces such as PMMA, COC and PC and low haze. Since the cured mass which is obtained is exposed to sun light and high temperatures during service, it is another object of the present invention to use HDP, monomers and oligomers that are resistant to UV light induced degradation and to thermal induced degradation.

In some embodiments, the concentration of the at least one HDP in the formulation is at least 10% of the total weight of the formulation. In other embodiments, the concentration is between 10 and 90% of the total weight of the formulation. In other embodiments, the concentration is between is 15 and 75% of the total weight of the formulation. In still further embodiments, the concentration is between 20 and 65% of the total weight of the formulation.

The unsaturated monomer or oligomer is selected so as to be stable against degradation induced by UV radiation (UV light) or heat (as polymerized/cross-linked matter), namely not to undergo degradation under such conditions, be it short term or long term. Each of said at least one unsaturated monomer or oligomer has at least one reactive group per molecule, said reactive group being selected from acryl, vinyl, allyl and unsaturated polyester. Typical oligomers and monomers that provide light and heat stable polymers are of the aliphatic, cycloaliphatic and/or the heterocyclic type. Polymers having aromatic groups (as part of the main backbone or as pendant or end-groups) should be avoided.

Typically, the monomers are selected amongst mono, di, tri or polyfunctional moluecleus having a molecular weight of between about 30 and 30,000 daltons. An oligomer would typically comprise two or more such monomers.

Non-limiting examples of said at least one unsaturated monomer are long chain alkyl acrylate or methacrylate esters such as lauryl methacrylate, butyl acrylate, octyl acrylate, decyl acrylate, iso-decyl acrylate, tridecyl acrylate, ethyl hexyl acrylate, ethoxylated ethyl hexyl acrylate, octyl decyl acrylate, di-ethylene glycol 2-ethylhexyl ether acrylate, tetra decyl acrylate, cetyl acrylate, stearyl acrylate, behenyl acrylate, polyethylene glycol mono acrylate and caprolactone acrylate 2-ethyl hexyl acrylate, polyethylene glycol acrylate, urethane acrylate, polyester acrylate and any methacrylate equivalent thereof.

Non-limiting examples of said at least one unsaturated oligomer are urethane acrylate and polyester acrylate.

In some embodiments, the encapsulant formulation comprises between about 5 and 75%, 85% or 95% of at least one acrylate monomer.

In other embodiments, the encapsulant formulation comprises between about 5 and 75% of at least one alkyl acrylate monomer.

In still further embodiments, the encapsulant formulation comprises between about 5 and 75% of at least one urethane acrylate monomer.

In other embodiments, the encapsulant formulation comprises between about 5 and 75% of at least one polyester acrylate monomer.

As stated above, the liquid encapsulant formulation comprises at least one photoinitiator, as well as at least one acrylic, methacrylic polyurethane and/or polyester polymer, monomer or oligomer, so the curing of said encapsulant is achieved within a few seconds to a few minutes upon exposure to UV light and/or visible light.

Non-limiting examples of said at least one photoinitiator are 2-hydroxy-2-methyl-1-phenyl-propan-1-one, 2,4,6-trimethylbenzoyl-diphenyl-phosphineoxide, 1-hydroxy-cyclohexyl-phenyl-ketone, bis(2,6-dimethoxybenzoyl)-2,4,4-trimethyl-pentyl phosphine oxide, 1-[4-(2-hydroxyethoxy)-phenyl]-2-hydroxy-2-methyl-1-propane-1-one, 2,2-dimethoxy-1,2-diphenylethan-1-one and 2-methyl-1[4-(methylthio)phenyl]-2-morpholinopropan-1-one.

In some embodiments, said at least one photoinitiator is reactive in the UV and visible spectrum. In some other embodiments, said at least one photoinitiator being activated by light in the visible spectrum, allows curing to be achieved when light is provided through glass or other UV screening protective layers. Non-limiting examples for such photoinitiators are phenyl phosphine oxides such as Irgacure 819 manufactured by Ciba, and Lucirin TPO manufactured by BASF.

The concentration of said at least one photoinitiator is between 0.05% and 10% of the total weight of the liquid formulation.

In order to provide adhesion of the encapsulant layer to, e.g., an inorganic protective layer such as glass, and to the surface of a photovoltaic module, the encapsulant formulation may further comprise at least one adhesion promoting agent selected from (1) monomers, oligomers or polymers having at least one acidic side or end groups, such as acrylic acid, a phosphoric acid derivative or any carboxylic acid derivative; Non-limiting examples of acidic oligomers are SR 9050 manufactured by Sartomer, Genorad 40 by Rahn, and maleic anhydride; and (2) organometallic adhesion promoter selected from an organo-silicon compound, an organo-titanium compound and an organo-zirconium compound such as Z-6030 manufactured by Dow Corning and NZ-37 and NZ-44 manufactured by Kenrich Petrochemicals.

In some embodiments, the encapsulant formulation comprises between about 0.1 and 10% of at least one adhesion promoter of type (1) above and/or between about 0.01 and 5% of at least one adhesion promoter of type (2).

In other embodiments, the addition of at least one addition promoter of type (2) to the encapsulant formulation, particularly where said at least one addition promoter is at least one organo-silicone, provides further crosslinking enabled by moisture curing over long periods of time.

In some embodiments, the encapsulant formulation of the invention comprises between 5 and 50% of at least one acrylic polymer or oligomer, between 5 and 50% of at least one acrylic monomer and between 0 and 25% of at least one plasticizer. In some embodiments, the at least one plasticizer is an aliphatic plasticizer, such as esters of adipic acid, Eastman 168 Xtreme Plasticizer manufactured by Eastman and VELSICOL DOA manufactured by Velsicol.

One exemplary formulation according to the present invention comprises:

1. at least one acrylic oligomer or monomer in an amount of at least 5% of the total weight of the formulation;

2. at least one aliphatic plasticizer in an amount ranging from 0 to 70% of the total weight of the formulation;

3. at least one polymer selected from (1) poly(acrylic or methacrylic acid ester or amide or urethane) including copolymers and terpolymers thereof; (2) PVB including copolymers and terpolymers thereof; (3) cyclic olefin; (4) aliphatic polyester; (5) aliphatic polyether and (6) aliphatic polyurethane in an amount ranging from 0 to 70% of the total weight of the formulation;

4. at least one hindered amine light stabilizer (HALS) in an amount ranging from 0 to 10% of the total weight of the formulation;

5. at least one organo-metallic adhesion promoter selected from silane, siloxanes, silazenes, titanates, zirconates and aluminates in an amount ranging from 0 to 10% of the total weight of the formulation;

6. at least one photoinitiator in an amount between 0.05% and 10% of the total weight of the formulation;

7. at least one acidic monomer and/or oligomer and/or polymer in an amount ranging from 0 to 50% of the total weight of the formulation; and

8. optionally at least one additive selected from UV-absorber, antioxidant, dye, pigment, tackifier, curing synergist, organic peroxide

In some embodiments, the at least one acrylic monomer is selected from are lauryl methacrylate, butyl acrylate, octyl acrylate, decyl acrylate, iso-decyl acrylate, tridecyl acrylate, ethyl hexyl acrylate, ethoxylated ethyl hexyl acrylate, octyl decyl acrylate, di ethylene glycol 2-ethylhexyl ether acrylate, tetra decyl acrylate, cetyl acrylate, stearyl acrylate, behenyl acrylate, polyethylene glycol mono acrylate and caprolactone acrylate 2-ethyl hexyl acrylate, polyethylene glycol acrylate and any methacrylate equivalent thereof.

The oligomers and polymers are selected amongst those having any one or more of the above monomers.

In some embodiments, the at least one aliphatic plasticizer is selected from adipic acid mono and di-ester, azelaic acid mono and di-ester, glutaric acid mono and di-ester, maleic acid mono and di-ester, and sebacic acid mono and di-ester.

In some embodiments, the at least one polymer is selected from poly alkyl methacrylate or acrylate such as ELVACITE manufactured by Lucite, PVB such as S-LEC B by Sekisui and BUTVAR by Solutia, cyclic olefin such as TOPAS manufactured by Topas advanced polymers, poly methyl methacrylate (PMMA), polyurethane acrylates such as GENOMER 4256 manufactured by Rahn, amino resins such as CYMEL manufactured by Cytec, and hydrogenated butadiene rubber such as LIR-200 manufactured by Kuraray.

The at least one HALS is, for example, TINUVIN 123 and 292 manufactured by CIBA.

Example for the at least one organo-metallic adhesion promoter are 3-(trimethoxysilyl)propyl methacrylate such as Z-6030 silane manufactured by Dow Corning, vinyltriethoxysilane, tetrapropyl orthosilicate, titanium(IV) butoxide such as that sold as TYZOR TBT by Du Pont, zirconium acrylate, organo-titanates and organo zirconates such as those sold by Kenrich petrochemicals as Ken-React additives, coordinate zirconates, neoalkoxy zirconates, zirconium propionate, Zircoaluminates, and Zirconium acetylacetonate.

The encapsulant formulation of the invention comprises also at least one photoinitiator which initiates polymerization and cross-linking of the unsaturated monomer or oligomer and said at least one adhesion promoting monomer or oligomer to form a dimensionally stable, soft and elastic encapsulant mass.

Non-limiting examples of said at least one photoinitiator are 2-hydroxy-2-methyl-1-phenyl-propan-1-one, 2,4,6-trimethylbenzoyl-diphenyl-phosphineoxide, 1-hydroxy-cyclohexyl-phenyl-ketone, bis(2,6-dimethoxybenzoyl)-2,4,4-trimethyl-pentyl phosphine oxide, 1-[4-(2-hydroxyethoxy)-phenyl]-2-hydroxy-2-methyl-1-propane-1-one, 2,2-dimethoxy-1,2-diphenylethan-1-one and 2-methyl-1[4-(methylthio)phenyl]-2-morpholinopropan-1-one.

In some embodiments, said at least one photoinitiator is selected to be activated by light in the visible spectrum, so that curing may be achieved when light is provided through glass or other UV screening protective layers. Examples of such photoinitiators are phenylphosphineoxides such as Irgacure 819 manufactured by Ciba, and Lucirin TPO manufactured by BASF.

The acidic monomers may be selected from acrylic and methacrylic acid, maleic anhydride, SR 9050 by Sartomer and Genomer 7154 manufactured by Rahn.

As stated hereinabove, the encapsulant formulation is a liquid at room temperature. The formulation may be prepared by first forming two separate bulk formulations, in the form of an adhesive Part A and Part B, which may be combined to form the encapsulant formulation at a desired point in time, prior to application. Alternatively, the encapsulant may be prepared by mixing the ingredients into one formulation to thereby obtain a ready-for-use encapsulate.

In one example, an adhesive Part A formulation may be prepared by first dissolving the solid or viscous liquid polymers in the monomers and/or oligomers used to provide a “syrup”, which is herein referred to as Part A. In the next stage, the solid or liquid additives such as the at least one photo initiator, at least one stabilizer, at least one UV absorber, peroxides, azo, catalysts, etc., are added into the plasticizer to obtain an additive liquid concentrate, herein referred to as Part B. The two parts may be stored separately and mixed to form a clear solution prior to application.

The encapsulant formulation thus prepared may be applied by any means known in the art. In some embodiments, the encapsulant formulation is dispensed onto the open PV module before assembly, without applying any pressure or force, or by applying a low pressure derived from the weight of the assembled components.

In some other embodiments, the formulation is applied by pumping the encapsulant onto a substrate or into a pre-made cavity to be filled. The pressure required to pump the liquid into the cavity is usually in the range of zero (free pouring) to about 1 atmosphere gauge. In some embodiments, the pressure is 0.5 atmosphere gauge. In other embodiments the pressure is between 0.1 and 0.4 atmosphere gauge. Examples to useful pumping methods are pneumatic dispensing, extrusion and syringe dispensing.

In some embodiments, the formulation is applied by pouring.

After application, curing of said formulation is enabled by means of UV and/or visible light, heat, IR irradiation or combinations thereof. Such curing provides an encapsulant layer thickness ranging from 10 microns to 5 millimeters. Typically, the formulations of the invention are cured to at least 90% conversion within 1 to 1,000 seconds.

In some embodiments, curing of the uncured liquid encapsulant (e.g., to at least 50% conversion of unsaturated groups) is achieved by employing a UV and/or visible light generated by a source selected from a mercury lamp, a plasma ignited lamp, a fluorescent bulb, a light emitting diode (LED), a halogen lamp and natural sun light. In other embodiments, the curing process comprises a curing step employing an artificial light (e.g., so as to provide conversion sufficient for handling), optionally followed by a further curing step initiated by natural sun light.

The encapsulant formulations and processes disclosed herein, enable high speed and economical manufacturing of PV modules, without the need for lamination under high pressure and heat (as is the case with existing technology which employs EVA and PVB), long curing periods and expensive surface treatments (as is the case for example with addition curing silicone elastomers).

The encapsulant (at the uncured liquid state) according the present invention may additionally be cured onto a plastic or elastic mass by means of any one or more of free radical mechanism, cationic mechanism, anionic mechanism, condensation reaction, addition reaction, Michael addition reaction, and ring opening mechanism. The curing may take place at both low temperatures (ambient or lower) or elevated temperatures.

Unlike thermosetting silicone that has poor adhesion to transparent (amorphous) plastic materials such as PMMA, COC and PC, the encapsulant of the present invention has excellent adhesion to thermoplastic and thermosetting materials such as PMMA, COC and PC without needing surface pretreatment, primer or any other adhesion promoting steps. The presence of the low molecular weight monomers and plasticizers, especially unsaturated aliphatic esters such as acrylic and methacrylic acid esters enables mild swelling of the substrate by the encapsulant, so as an “alloy” interphase is formed thereby adhesion is achieved. The swelling and miscible interface layer formation is achieved without stress-cracking of said transparent (amorphous) polymeric surfaces.

In some embodiments, the cured layer of the encapsulant according to the present invention has adhesion peel strength to PMMA of greater than 1 pound per linear inch (PLI).

In some embodiments, the cured layer of the encapsulant according to the present invention has adhesion peel strength to PMMA of greater than 3 pound per linear inch (PLI).

In some embodiments, the cured layer of the encapsulant according to the present invention has adhesion tensile strength to PMMA of greater than 0.001 kilograms per square cm.

In other embodiments, the cured layer has a refractive index of between 1.4 and 1.6.

Another method which was employed to demonstrate the improved adhesion (and the ability to withstand the stresses generated due to the thermal mismatch between the PV cell and the polymeric surface, e.g., glass and the (amorphous) transparent substrate) of the encapsulant of the invention to PMMA and glass is by bonding two plates, 100 mm×100 mm in size and 3-mm thick, one made of glass and the other of PMMA. The bonding is achieved by applying 200-600-micron thick layer of said encapsulant between the plates, and curing by exposing to UV/visible light emitted from a medium pressure mercury lamp. In a typical example, the bonded plates were subjected to thermal cycles ranging from −40° C. to +85° C. A laminate bonded with commercially available EVA film, failed after two cycles. A laminate bonded with commercially available addition type silicone elastomer (PV 6010 manufactured by Dow Corning) failed after three cycles. A laminate comprising an adhesive layer according the present invention, passed 100 cycles and even 250 cycles without any delamination.

Unlike thermoplastic adhesives, the encapsulant according to the present invention requires minimal pressure or no pressure at all and usually flows and wets well at ambient, without needing external heat. Unlike the lamination processes employing thermoplastic adhesives (such as EVA or PVB), the manufacturing process employing the encapsulant of the invention is fast and economical. The fact that heating is not required for lamination enables the manufacturing of CPV from relatively low heat deflection temperature materials, such as PMMA. Lamination of PMMA by standard EVA or PVB encapsulants, at a temperature in the range of 100 to 160° C., under lamination pressure, results in the PMMA being irreversibly deformed and its optical properties deteriorated.

The cured encapsulant of the invention has a tensile storage modulus which varies from 100 MPa to 0.0001 MPa (a soft gel), when measured by Dynamic Mechanical Analysis (DMA) at 23° C., at 1 Hz. In some embodiments, the modulus range is from about 20 MPa (tensile storage modulus) to 0.0001 MPa, when measured by Dynamic Mechanical Analysis (DMA) at 23° C. In order to minimize stresses at low temperature, the encapsulant is characterized by low modulus of elasticity at −40° C. The cured encapsulant of the invention has a modulus which varies from 100 MPa to 0.01 MPa, when measured by Dynamic Mechanical Analysis (DMA) at −40° C.

Without wishing to be bound by theory, the low modulus minimizes stresses between the inorganic protective layer (glass for example) and the bonded plastic layers. The stresses are generated due to thermal mismatch (difference in coefficient of thermal expansion), shrinkage during curing and due to difference in humidity uptake. This property is of high importance as the module is exposed to thermal cycles in the range of +85° C. to −40° C. Current thermoplastic adhesives (such as EVA and PVB) are too rigid for this purpose. Silicone adhesives are suitable for this purpose, but have poor adhesion to such (amorphous) transparent plastic materials, they tend to be inhibited easily and require long curing times at temperatures of 80° C. or higher.

In some embodiments, the cured encapsulant of the present invention has a modulus of less than 50 MPa and shore A hardness of lower than 85 A, lower than 54 A or lower than 20 A.

In some other embodiments, the cured encapsulant mass has a modulus of lower than 100 Megapascals (MPa). In other embodiments, the cured mass has a modulus of lower than 50 Megapascals (MPa). In still other embodiments, the cured mass has a modulus of lower than 20 Megapascals (MPa) at 23° C.

In some further embodiments, the cured encapsulant has a light transmission through 500 micrometers (microns) of cured mass of at least 85% of original light intensity in the wavelength range of 300 to 800 nanometers.

One important requirement is the maintenance of optical clarity after long term exposure to heat and humidity. Usually, highly cross-linked adhesives, maintain their clarity, due to their high crosslinking density that avoids phase separation and crystallization. Since the encapsulant of the invention is soft (low crosslinking density and high content of plasticizers or low molecular weight oligomers), a phase separation during aging, is a major concern. Surprisingly, a formulation comprising at least one acrylic, aliphatic polyester or polyurethane polymer or oligomer, and at least one acrylic monomer or oligomer, at least one photo initiator and optionally at least one plasticizer and cured by exposing to UV and/or visible light, maintains its optical clarity for periods as long as 10,000 hours in accelerated UV weathering, despite its low modulus of elasticity and low cross-linking density.

In order to avoid brittleness of the cured encapsulant layer, at low temperatures, that may be expected during winter in many areas, the encapsulant, in some of its embodiments, has a glass transition temperature (Tg) of lower than 30° C.; in other embodiments, lower than 10° C., still other embodiments, lower than −10° C., lower than −20° C., lower than −30° C., or lower than −40° C. The glass transition is measured by Thermal Mechanical Analysis (TMA), dynamical mechanical analysis (DMA) or by Differential Scanning calorimetry (DSC). The Tg can be adjusted by selection of the monomers, wherein high content of long chain alkyl acrylates or polyether acrylates, affect the Tg. For example, the Tg of a homopolymer of isodecyl acrylate is −60° C. and the Tg of a homopolymer of 2(2-ethoxyethoxy) ethyl acrylate (EOEOEA) is −54° C. Thus, a high content of such monomers enables a Tg which is lower than −10° C. and even lower than −20° C. The homopolymer of tetrahydro furfuryl acrylate (THFA) has Tg of −28° C., and since THFA has excellent adhesion to PMMA, an amount of 5-50% endows the encapsulant with both lower Tg and excellent adhesion. In some embodiments, the formulation comprises a combination of THFA and EOEOEA. These monomers or similar, may be part of the acrylic polymer or oligomer, as well as portion or all of the unsaturated monomer.

Another effective way to lower the Tg is by increasing content of a plasticizer, typically selected amongst linear, branched and/or ethoxylated aliphatic mono or di-acid plasticizers.

The encapsulant according to the present invention additionally has similar or even better resistance to oxidation and photo-degradation than EVA and PVB, a resistance that is evident from the lower tendency to yellow and to crack over time. This improved resistance is provided by the elimination of vinyl acetate groups that are typical to EVA and PVB, since the acetate group is disassociated from the main chain during exposure to heat and/or UV light. The by-product of this un-desired reaction is acetic acid that causes corrosion of the PV cell conductors. The encapsulant formulation comprises no acetate groups, and thus is much more resistant against thermal and photo induced degradation. Another advantage of the encapsulant according the present invention is the minimal thermal history during processing, since neither extrusion, nor high temperature lamination is required. This lowered thermal history provides polymer mass that has lower unsaturated groups, lower gel content and lower weakened points.

In another aspect of the invention, there is provided a PV module comprising at least one bonding layer of a cured formulation according to the invention.

In some embodiments, the PV module comprises at least one PV cell and at least one surface selected from PMMA, COC and PC, wherein bonding between said cell and said at least one surface is provided by a bonding layer comprising the encapsulant formulation according to the present invention.

As used herein, a PV module consists of several interconnected cells or thin films (being capable of providing electrical voltage and/or current in response to light) that are embedded or bonded to one or two, e.g., (amorphous), transparent plastic (e.g., PMMA, COC or PC) surfaces (e.g., prisms, lenses, reflectors), with a bonding layer (encapsulant) of a formulation according to the invention. In some embodiments, the bonding layer is the cured film or mass derived from a formulation of the present invention.

Typically, the PV module has a transparent front (top) side (being glass or a polymeric material), at least one optical element (a prism, a lens, a frensel lens, a non-flat optical concentrator, etc) layer made of, e.g., an amorphous transparent plastic material and an encapsulated PV cell. The backside may or may not be transparent.

Between the front side and the back side, the plastic optics is first placed above the PV cells (one or more) and encapsulated with the formulation of the present invention. The PV module may comprise any number of PV cells. In some embodiments, the PV module comprises more than 1 cell. In other embodiments, the PV module comprises at least 2 cells.

The individual PV cells in the module may be any device, semiconductor (of any semiconductor material, being in the form of a single crystal, poly-crystalline or amorphous) or organic or inorganic that provides electrical potential and/or current when irradiated by light, particularly in the range of wavelengths of 200 to 1,200 nanometers. The PV cells are typically interconnected with thin contacts on the upper and bottom side of the, e.g., semiconductor material.

In fact, the assembly may be any optical assembly having at least one polymeric surface to be bonded as detailed herein. In the assembly, the cured encapsulant mass is derived from the liquid formulation of the invention, as defined.

The assembly may be the PV module, as defined.

In some embodiments of the invention, the PV module is a concentrating photovoltaic module (CPV) having three or more layers including the PV cell, a bonding layer and a concentrating object. In some embodiments, said CPV is of the structure shown in FIG. 1. In the CPV of FIG. 1, layer (1) is a concentrating object (CO) that collects light (e.g., sunlight) and concentrates it on the photovoltaic cell (5). As a person versed in the art appreciates, the light intensity on interface between layers (4) and (5) is higher than the light intensity on interface of the outer, air-exposed layer (3) and the surrounding air. The CO comprises of polymeric material having transparency in the UV-visible spectrum, high durability against thermal and photo-degradation and ease of manufacturing and is selected in a non-limiting fashion from poly methyl methacrylate (PMMA), polycarbonate (PC) and cyclic olefin (COC).

In order to provide protection from erosion, hydrolysis and microbial attack, the above CPV multilayer structure according to the present invention has an outer inorganic transparent layer (3) having thickness between 0.1 to 10 millimeters, said outer inorganic layer being selected from glass, quartz, alumina, fused silica and sol-gel coated polymeric sheet. In some embodiments, the protective layer is glass.

The photovoltaic cell constituting layer 5 may be any device, semiconductor or organic or inorganic that provides electrical potential and/or current when irradiated by light, especially in the range of wavelengths of 200 to 1200 nanometers.

Layers (2) and (4) of the CPV of FIG. 1 are each a bonding layer comprising an encapsulant formulation according to the invention. Such a multilayered CPV may be manufactured by applying, as disclosed above, the formulation of the invention onto at least one face of layers 1 and 3 and at least one face of layers 1 and 5, and assembling the layers one on top of the other such that a multilayer is achieved. Layers 2 and 4 are then cured by means of radiation including one or more of UV, visible light, IR, and/or heating.

### BRIEF DESCRIPTION OF THE DRAWINGS

In order to understand the invention and to see how it may be carried out in practice, some embodiments will now be described, by way of non-limiting example only, with reference to the accompanying drawings, in which:

FIG. 1 is an exemplary CPV according to the present invention.

FIG. 2 is an exemplary CPV according to the present invention.

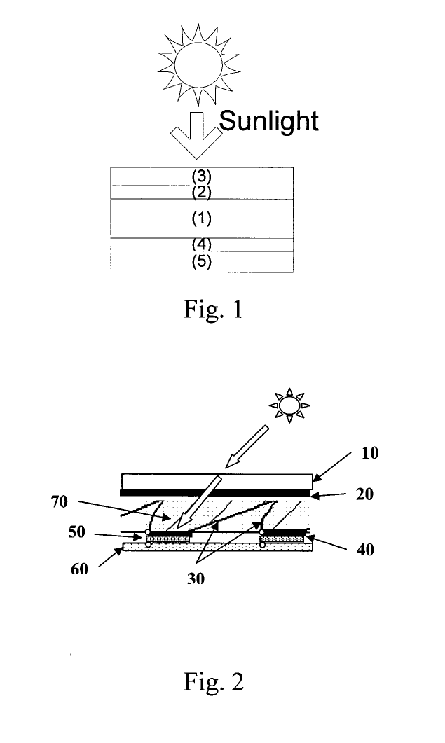

### DETAILED DESCRIPTION OF EMBODIMENTS

PV modules prepared according to the present invention included an outer layer made of low iron ultra-clear solar glass (such as Saint-Gobain SECURIT ALBARINO S 3.2-4mm thick with light transmission level of 91.5%). The concentrating object employed was in the form of a layer of PMMA resin PLEXIGLAS 8N manufactured by Evonik, and the photovoltaic cell was a silicone cell, 200 μm thick.

Different encapsulant formulations according to the present invention have been utilized in the construction of various CPV modules, as shown in Table 1 below.

TABLE 1
different encapsulant formulation according to the present invention: EOEOEA- 2-(2-ethoxyethoxy)
ethyl acrylate; Ur-Acryl (aliphatic urethane acrylate)- CN 9001, manufactured by Sartomer;
polyacrylate solution- Doublemer 353, manufactured by Double Bond Chemical from Taiwan; Plasticizer-
bis[2-(2-butoxyemoxy)ethyl] adipate; HALS- Tinuvin 292 manufactured by CIBA; photo initiator-
Irgacure 819, manufactured by CIBA; silane- 3-(methacryloyloxy) propyl]trimemoxysilane,
sold as Dow Corning ® product Z-6030; and peroxide- benzoyl peroxide.

| Formula | | | Polyacrylate | acrylic | | | Photo | | |
|---|---|---|---|---|---|---|---|---|---|
| # | EOEOEA | Ur-Acryl | solution | acid | Plasticizer | HALS | initiator | silane | Peroxide |
| 1 | 26 | 62 | 0 | 5 | 0 | 3 | 1 | 3 | 0 |
| 2 | 34 | 0 | 43 | 5 | 14 | 0 | 0.5 | 3.5 | 0 |
| 3 | 31 | 0 | 43 | 5 | 14 | 3 | 0.5 | 3.5 | 0 |
| 4 | 31 | 0 | 43 | 5 | 14 | 3 | 0 | 3 | 1 |
| 5 | 8.5 | 0 | 60 | 0 | 30 | 1 | 0.5 | 0 | 0 |

Formulas 1, 2, 3 and 5 according to the present invention were cured by medium pressure mercury lamp providing 75-100 mW/cm² in the range of 320-390 nm for period of 30 seconds. Formula 4 according to the invention was cured 30 minutes at 100° C.

Adhesion (encapsulation) quality was evaluated by exposure to 500 thermal cycles at a temperature between −40 to +85° C. All 4 formulations were found to provide the required encapsulation.

Samples of CPV according to the present invention were exposed to QUV accelerated ageing (light penetrated from glass side), following the protocol:

irradiation by UVB 313 bulb;

8 hours light, black panel temperature of 70° C.;

4 hours dark, condensation phase, 50° C.;

Total hours: 5000.

Formulas 2, 3 and 4—showed no discoloration and no cracking of the bonding adhesive layers and PMMA object. Formula 1 showed a slight yellowing.

### COMPARATIVE EXAMPLE 1

UV curable acrylate based formulas that comprised aromatic monomers, oligomers and plasticizers, provided good adhesion to PMMA and glass/cell, but turned dark brown after exposure to UV light in the QUV accelerated test.

### COMPARATIVE EXAMPLE 2

Two-component aliphatic polyurethane (aliphatic polyester polyol, cured by aliphatic tri-isocyanate, and plasticized by aliphatic plasticizer) provided sufficient UV resistance, but had poor adhesion to PMMA and medium-poor adhesion to the glass and cell.

### COMPARATIVE EXAMPLE 3

A reference PV module wherein adhesive layers were PV 6010 addition type silicone gel encapsulants, manufactured by Dow corning, failed after less than 5 cycles due to poor adhesion between the silicone encapsulants and the PMMA layer. The adhesion was so poor, that in some samples, delamination and blisters were observed immediately after curing, prior to any ageing test.

FIG. 2 illustrates the structure of an exemplary CPV panel according to the present invention. This non-limiting CPV solar panel was assembled from the following layers—
1. a top cover glass (10);
2. a bonding layer (20) comprising a mixture of 55% Doublemer 353 acrylic polymer/acrylic monomer mixture manufactured by Double-Bond Chemical from Taiwan, 25% EOEOEA monomer, 5% acrylic acid, 3% Dow Corning® product Z-6030 adhesion promoter, 0.5% photo initiator Lucirin TPO manufactured by BASF and 11.5% plasticizer bis[2-(2-butoxyethoxy)ethyl] adipates. The mixture has a viscosity at ambient lower than 5,000 centipoises and it is applied between the glass and PMMA and between the PV cell and PMMA. The liquid encapsulant/adhesive propagates spontaneously at ambient with no need to apply heat/pressure, until gaps are filled. The layer is then cured (cross-linked) by exposing to medium pressure mercury UV source, for 30 seconds, so as the cured bonding layer is non-tacky (or in some cases tacky), resilient, soft, transparent, void-free, haze-free and bonded very good to glass, PMMA and PV cell.
3. Prism concentrators made of PMMA and mirror foils (30). The PMMA is injection molded and the metal minors are bonded to the PMMA prism by same bonding layer used for glass-PMMA and PV cell-PMMA bonding;
4. a bonding layer (40) of the same or a similar material as that in layer (20);
5. a PV cell with conducting ribbons (50); and
6. a back sheet (60) made of anodized aluminum for sealing from humidity and oxidation, and for heat dissipation.

Light rays entering the panel are trapped in the prism (via total internal reflection) and directed toward the PV cell.

1.-33. (canceled)

34. An optical assembly comprising at least one polymeric surface and at least one layer of a cured encapsulant, wherein the encapsulant, in the uncured liquid state, comprises at least one high durability polymer (HDP), at least one unsaturated monomer and/or oligomer, and at least one photoinitiator.

35. The assembly according to claim 34, being a photovoltaic module.

36. The assembly according to claim 35, wherein the photovoltaic module comprises at least one photovoltaic cell.

37. The assembly according to claim 34, wherein the at least one polymeric surface is glass or a transparent plastic.

38. The assembly according to claim 36, wherein the at least one photovoltaic cell is bonded to at least one polymeric surface, wherein bonding between the photovoltaic cell and the at least one polymeric surface is provided by a bonding layer comprising the cured encapsulant.

39. The assembly according to claim 36, wherein the photovoltaic cell is a device that provides electrical potential and/or current when irradiated by light, in the range of wavelengths of from 200 to 1,200 nanometers.

40. The assembly according to claim 39, being a concentrating photovoltaic cell.

41. The assembly according to claim 40, comprising a top glass, a prism or a lens or a fresnel lens or a non flat optical concentrator, at least one photovoltaic cell, and a back cover or sheet.

42. The assembly according to claim 34, wherein the cured encapsulant is a non-tacky or tacky, resilient, soft, transparent, void-free, haze-free bonding layer.

43. The assembly according to claim 34, wherein the cured encapsulant has a Tg lower than 30° C., lower than 10° C., lower than −10° C., lower then −20° C., lower than −30° C., or lower than −40° C.

44. The assembly according to claim 34, wherein the cured encapsulant has a light transmission through 500 micrometers (microns) of cured mass of at least 85% of original light intensity in the wavelength range of from 300 to 800 nanometers.

45. The assembly according to claim 34, wherein the cured encapsulant has tensile modulus of elasticity of from 100 MPa to 0.0001 MPa, 20 MPa to 0.0001 MPa, or from 100 MPa to 0.01 MPa, as measured at 1 Hz at 23° C. or −40° C.

46. The assembly according to claim 34, wherein the cured encapsulant has a refractive index of from 1.4 to 1.6.

47. A photo/thermo curable liquid encapsulant formulation for optical assemblies having at least one polymeric surface, the formulation comprising at least one high durability polymer (HDP), at least one unsaturated monomer and/or oligomer, and at least one photoinitiator.

48. The formulation according to claim 47, wherein the at least one polymeric surface is a transparent plastic.

49. The formulation according to claim 47, having a viscosity at 25° C. of between 50 and 1,000 centipoises (cps), between about 150 and 5,000 cps, or between 250 and 10,000 cps, at a shear rate of 10 sec⁻¹.

50. The formulation according to claim 47, wherein the at least one HDP is selected from the group consisting of an acrylic polymer, an aliphatic polyester, an aliphatic polyurethane, and polyvinyl butyral.

51. The formulation according to claim 47, wherein the at least one unsaturated monomer is selected from acrylic acid or methacrylic acid and derivatives thereof.

52. The formulation according to claim 47, wherein the at least one photoinitiator is able to initiate polymerization and cross-linking when exposed to UV and/or visible light.

53. A cured encapsulant mass prepared by providing a formulation according to claim 47, and curing the formulation.

54. The formulation according to claim 51, wherein the derivatives are selected from the group consisting of esters, urethanes, and amides thereof; alkyl acrylate monomer; urethane acrylate monomer; polyester acrylate monomer; and unsaturated polyester.
